(19) United States
(12) Patent Application Publication
(10) Pub. No.: US 2025/0070070 A1
(43) Pub. Date: Feb. 27, 2025

(54) SEMICONDUCTOR PACKAGE AND METHOD FOR MANUFACTURING A SEMICONDUCTOR PACKAGE

(71) Applicant: Huawei Digital Power Technologies Co., Ltd., SHENZHEN (CN)

(72) Inventors: Mirko BERNARDONI, Munich (DE); Lasse Petteri PALM, Nuremberg (DE); Gilberto CURATOLA, Nuremberg (DE)

(21) Appl. No.: 18/945,986

(22) Filed: Nov. 13, 2024

Related U.S. Application Data
(63) Continuation of application No. PCT/EP2022/063338, filed on May 17, 2022.

(51) Int. Cl. H01L 23/00; H01L 21/48; H01L 23/31; H01L 23/367; H01L 23/495; H01L 25/18

(52) U.S. Cl. CPC H01L 24/14; H01L 21/486; H01L 23/3121; H01L 23/3677; H01L 23/49568; H01L 23/49575; H01L 24/16; H01L 25/18; H01L 2224/1403; H01L 2224/14051; H01L 2224/14132; H01L 2224/14133; H01L 2224/14179; H01L 2224/16145; H01L 2225/06513; H01L 2225/06589; H01L 2924/1815

(57) ABSTRACT

The present disclosure is related to the field of semiconductor devices and packaging, and to heat transfer in a semiconductor package. The present disclosure provides a semiconductor package and a method for fabricating the semiconductor packet. The semiconductor package comprises a semiconductor device, a heat sink, and a plurality of vias. The plurality of vias is arranged between the semiconductor device and the heat sink to transfer heat from the semiconductor device to the heat sink. The plurality of vias further forms a non-uniform distribution of vias over the device face.

### CROSS-REFERENCE TO RELATED APPLICATIONS

This application is a continuation of International Application No. PCT/EP2022/063338, filed on May 17, 2022, the disclosure of which is hereby incorporated by reference in its entirety.

### TECHNICAL FIELD

The present disclosure is related to the field of semiconductor devices and packaging. In this field, the disclosure is concerned with heat transfer in a semiconductor package. The disclosure proposes a semiconductor package that includes a semiconductor device and a heat sink. Further, the present disclosure relates to a method for manufacturing the semiconductor package.

### BACKGROUND

A conventional semiconductor package can comprise one or more semiconductor devices. A semiconductor device produces heat when it is operated, for instance, when it is supplied with electricity to fulfil its functions.

The conventional semiconductor package typically comprises a heat sink, which is configured to help in dissipating away heat produced by the semiconductor device. In order to transfer heat from the semiconductor device to the heat sink, the heat sink and the semiconductor device may be thermally connected.

When the semiconductor device of the conventional semiconductor package produces heat, more or less heat can be transferred to the heat sink depending on the quantity of heat produced by the semiconductor device at the location of the thermal connection. As a result, the semiconductor device can have some regions that become much hotter or colder than other regions, which may lead to too little dissipation of heat away from the semiconductor device.

### SUMMARY

In view of the above, the present disclosure aims to provide ways of improving the heat dissipation away from a semiconductor device in a semiconductor package. Objectives of the present disclosure include to design and manufacture a semiconductor package, which enhances the control of the distribution of heat in the semiconductor device, and enables to adapt it accurately to the design requirements that apply to the semiconductor device and to the semiconductor package.

These and other objectives are achieved by the solution of this disclosure as described in the independent claims. Advantageous implementations are further defined in the dependent claims.

A first aspect of this disclosure provides a semiconductor package comprising: a semiconductor device which produces heat when being operated; a heat sink, and a plurality of vias arranged between a device face of the semiconductor device and the heat sink, the plurality of vias being configured to transfer heat from the semiconductor device to the heat sink, wherein the plurality of vias forms a non-uniform distribution of vias over said device face.

The non-uniform distribution of vias allows to adjust temperature gradients, hence, the thermal field across the plurality of vias and over the device face. This in turn enables to enhance the control of the distribution of heat in the semiconductor device, and to accurately adapt this distribution of heat to any design requirements that may apply to the semiconductor device and to the semiconductor package, respectively.

As the plurality of vias is configured to transfer heat from the semiconductor device to the heat sink, the plurality of vias may be thermally connected with the semiconductor device on the one hand, and with the heat sink on the other hand.

In an implementation form of the first aspect, the plurality of vias may comprise at least two sets of vias having different respective surface densities of vias.

The surface density of vias may be measured as a ratio (for example in %) of the cumulated surface occupied by the vias (for example in mm²) in a given area over the total surface of said given area (for example in mm²). For example, the more vias of a given individual surface occupy the given area, the larger the surface density of vias in this given area may be. Besides, the bigger the individual surfaces of the vias are in the given area, the larger the surface density of vias in this given area may be.

Thus, such sets of vias enable to design the non-uniform distribution of vias, in which there can be at least two different respective surface densities of vias.

When the semiconductor device is operated, a relatively large surface density is likely to transfer a relatively large heat flux; conversely, a relatively small surface density is likely to transfer a relatively small heat flux.

In various implementations, the plurality of vias may be split into more than two sets of vias having different surface densities of vias, for example three, four, six, ten or more sets of vias.

In an implementation example, the surface density of vias may be substantially constant over each set of vias.

In an implementation form of the first aspect, a surface density of vias over a first area of said device face may be larger than a surface density of vias over a second area of said device face.

These various surface densities of vias over the first and second areas enable to adapt the thermal field, hence, the temperature gradients, to predetermined requirements, in order for example to increase the service life of the semiconductor device.

The first area may be kept at a temperature that is relatively close to a temperature of the second area when the semiconductor device is operated. Indeed, the first area can be cooled down more than the second area where the thermal resistance is relatively higher and the heat flux relatively lower. Balancing temperatures between various areas may avoid or lessen undesirable temperature gradients between these various areas.

In an implementation example, the respective surface densities of the first area and of the second area may be selected such that the temperature of the first area is slightly lower than the temperature of the second area.

In an implementation example, the first area may be a lateral area of the device face, while the second area may be a central area of the device face. The lateral area may be a peripheral area totally or partially surrounding a central area.

In an implementation example, the non-uniform distribution of vias in the plurality of vias may be defined in a plane parallel to the device face, for example in a cross-section. The device face may be substantially planar. The device face may be one of the largest, or the largest one, among the faces of the semiconductor device.

In various implementations, the plurality of vias may be split into more than two areas (first and second) having different surface densities of vias, for example three, four, six, ten or more areas.

In an implementation form of the first aspect, the surface density of vias over the first area of said device face may be between 2 and 100 times larger, for example between 10 and 50 times larger, than the surface density of vias over the second area of said device face.

Such a factor allows the heat flux flowing out of the first area to be larger or much larger than the heat flux flowing out of the second area. Accordingly, the first area can be cooled down more than the second area where the thermal resistance is relatively higher. This can balance larger temperature gradients between the various areas, e.g. the first and second areas.

In an implementation form of the first aspect, the first area of said device face may form a central area of said device face, and the second area of said device face may form a lateral area of said device face, the lateral area being for example a peripheral area surrounding the central area.

Such a configuration has its central, first area that allows the transfer of a larger heat flux than its lateral or peripheral second area. This configuration can achieve a thermal field as flat as possible for various types of semiconductor devices, where the center is hotter than the sides or periphery. Accordingly, the service life of the semiconductor device and of the semiconductor package may be increased and even maximized.

In an implementation form of the first aspect, the first area of said device face may represent between 20% and 60% of the entire area of said device face, and/or the second area of said device face may represent between 40% and 80% of the entire area of said device face.

In an implementation example, the first area is a central area that covers about 30% of the device face, while the second area is a peripheral area that covers about 70% of the device face.

In an implementation form of the first aspect, the surface density of vias over the first area of said device face may be between 20% and 100%, for example between 20% and 80%, and/or the surface density of vias over the second area of said device face may be between 0% and 50%, for example between 10% and 40%.

Such surface densities of vias may allow for sufficient heat fluxes to flow out of the first and second areas, while balancing the temperature gradients and the thermal field between the first and second areas, hence smoothing the thermal field across the device face.

In an implementation example, the surface density of vias over the first area (e.g. central area) of said device face may be uniform. Additionally or alternatively, the surface density of vias over the second area (e.g. lateral area) of said device face may be uniform.

In an implementation example, the surface density of vias over the first area of said device face may be selected such that the thermal conductivity through the first area of said device face is comprised between 50 W/m/K and 400 W/m/K, for example larger than 100 W/m/K, for example larger than 150 W/m/K. Additionally or alternatively, the surface density of vias over the second area of said device face may be selected such that the thermal conductivity through the second area of said device face is comprised between 1 W/m/K and 200 W/m/K, for example between 10 W/m/K and 100 W/m/K, for example between 20 W/m/K and 80 W/m/K.

Such thermal conductivities may allow sufficient heat fluxes to flow out of the first and/or second areas, hence out of the semiconductor device and toward the heat sink.

In an implementation form of the first aspect, the plurality of vias may comprise large vias and small vias, a large via having a larger cross-sectional area than a small via when measured parallel to said device face.

The large vias can transfer more heat than the small vias, or the large vias can transfer a given amount of heat distributed over a larger surface. The cross-sectional area may be measured in a plane parallel to the device face.

In an implementation form of the first aspect, a ratio of a cross-sectional area of a large via over a cross-sectional area of a small via may be between 1.5 and 1000, for example between 10 and 500.

Such a ratio can contribute to balancing the heat flowing out of different areas of the device face, hence out of the semiconductor device. The cross-sectional area may be measured in a plane parallel to the device face.

In an implementation example, each large via may have a width comprised between 50 μm and 1500 μm, for example between 100 μm and 500 μm, when measured in a plane parallel to said device face.

In an implementation example, the vias may be micro-vias. For example, the vias may have a height comprised between 50 μm and 1000 μm, for example between 300 μm and 600 μm, when measured in a longitudinal direction perpendicular to said device face.

In an implementation form of the first aspect, the vias may be thermal vias.

Thermal vias may be vias which conduct only heat, but which are not configured to supply electricity to the semiconductor device.

In an implementation example, the semiconductor package may further comprise electrical vias configured to supply electricity to the semiconductor device.

In an alternative implementation example, the electrical vias may be formed by the plurality of vias that are arranged in the non-uniform distribution of vias.

In an implementation form of the first aspect, the vias may be in direct contact with the heat sink.

Thermal resistance along the path between the semiconductor device and the heat sink can be small or even minimal.

In an implementation form of the first aspect, the plurality of vias may comprise at least two groups of vias, the shapes of the vias may differ from one group of vias to another group of vias when viewed in a cross-section parallel to said device face, said shapes of the vias being for example selected among rectangle, square, ellipse and circle.

In an implementation example, the plurality of vias may comprise a group of square vias and a group of rectangular, non-square vias, the group of rectangular, non-square vias being optionally surrounded by vias of the group of square vias.

In an embodiment of the first aspect, the non-uniform distribution of vias may be designed such that the plurality of vias comprises at least a central symmetry, a radial symmetry or an axial symmetry.

The temperature or thermal field in the operated semiconductor device may be adjusted to have substantially symmetrical shape.

In an embodiment, the non-uniform distribution of vias may be designed such that such that the plurality of vias does not present any symmetry. Thus, the thermal field in the operated semiconductor device may be adjusted to have a substantially asymmetrical shape.

In an embodiment of the first aspect, the non-uniform distribution of vias may be designed such that a gap between two neighboring vias increases as the distance of said two neighboring vias to the center of said device face increases.

Thus, the gap between two consecutive vias is larger near the sides or edges than in the center of the device face. The increasing function may for example be a power function with the exponent being equal to or greater than 2. The increasing function may for example be a geometric progression with a ratio larger than 1.

In an embodiment of the first aspect, the non-uniform distribution of the vias may comprise rows and columns, whereby a first gap between consecutive rows may vary in the plurality of vias, and a second gap between consecutive columns may vary in the plurality of vias, the first gap being for example different from the second gap.

The areas void of vias and lying between rows or columns can vary in size, which allows to adjust the temperature gradients and the thermal field for a given application of the semiconductor device.

In an embodiment, the first gaps (between rows) may generally be smaller than the second gaps (between columns). Alternatively, the first gaps (between rows) may generally be larger than the second gaps (between columns). Still alternatively, the first gaps may be substantially equal to the second gaps.

In an embodiment of the first aspect, the semiconductor device may be embedded in a thermally insulating material.

In an embodiment, the semiconductor device may be a chip, in particular an embedded chip. In an embodiment, the semiconductor device may be a microprocessor, a graphics processor, or an application specific integrated circuit (ASIC).

In an embodiment, the semiconductor package may form a system in package (SIP).

In an embodiment of the first aspect, the semiconductor package may further comprise a die supporting the semiconductor device, and a lead frame for carrying signals from and/or to the die, and the lead frame may be thermally connected with the heat sink.

In an embodiment, the semiconductor device may be directly mounted on the lead frame. The lead frame may be mounted on or part of the heat sink.

In an embodiment, on one side, the vias may be arranged in direct contact with the die or, alternatively, with the device face, and/or on another side, the vias may be arranged in direct contact with a thermally conductive layer, for example the lead frame.

In an embodiment, the lead frame may comprise a metallic layer, which may be made out of copper, aluminum, copper alloy and/or aluminum alloy.

A second aspect of this disclosure provides a method for manufacturing a semiconductor package, the method comprising: providing a semiconductor device which produces heat when being operated; providing a heat sink; and forming, for example by means of a laser beam, a plurality of vias arranged between a device face of the semiconductor device and the heat sink, the vias being configured to transfer heat from the semiconductor device to the heat sink; wherein the plurality of vias forms a non-uniform distribution of vias over said device face.

The method of the second aspect makes it possible to manufacture a semiconductor package in accordance with the first aspect described above. The method of the second aspect accordingly achieves all the advantages described above for the first aspect.

In an embodiment of the second aspect, the method may initially comprise: implementing a model of the semiconductor package on a computer; inputting a set of operating conditions in the computer; and processing, with the computer, a simulation of the thermal field in the semiconductor device as a function of said set of operating conditions.

The method of the second aspect may comprise further implementation forms, which correspond to the implementation forms of the semiconductor package of the first aspect. The implementation forms of the method may be such that the semiconductor package according to the implementation forms of the first aspect is manufactured.

### BRIEF DESCRIPTION OF DRAWINGS

The above described aspects and implementation forms will be explained in the following description of embodiments in relation to the enclosed drawings, in which

FIG. 1 shows a schematic cross-section of a part of a semiconductor package according to a first embodiment of the present disclosure;

FIG. 2 shows a schematic cross-section of a part of a semiconductor package according to a second embodiment of the present disclosure;

FIG. 3 is a diagram schematically plotting temperatures (in degrees Celsius) of a not-shown conventional semiconductor package and of the semiconductor package of FIG. 1 or 2, as a function of a position (in μm) along direction D shown in FIG. 1;

FIGS. 4 to 12 show an embodiment of the present disclosure;

FIG. 13 shows a schematic cross-section of a part of a semiconductor package according to an embodiment of the disclosure;

FIG. 14 shows a schematic cross-section of a part of a semiconductor package according to an embodiment of the disclosure;

FIG. 15 illustrates a method according to a second embodiment of the present disclosure for manufacturing a semiconductor package according to an embodiment of the disclosure;

FIG. 16 shows a schematic top perspective view of a part of a conventional semiconductor package;

FIG. 17 is a diagram schematically plotting temperatures (in degrees Celsius) of the semiconductor package of FIG. 16 as a function of a position (in μm) along direction D shown in FIG. 16;

FIG. 18 shows a schematic front view of a part of a semiconductor package according to an embodiment of the disclosure;

FIG. 19 is a diagram schematically plotting temperatures (in degrees Celsius) of the semiconductor package of FIG. 18 as a function of a position (in μm) along direction D shown in FIG. 18;

FIG. 20 shows a schematic front view of a part of a semiconductor package according to an embodiment of the disclosure;

FIG. 21 is a diagram schematically plotting temperatures (in degrees Celsius) of the semiconductor package of FIG. 20 as a function of a position (in μm) along direction D shown in FIG. 20;

FIG. 22 shows a schematic front view of a part of a semiconductor package according to an embodiment of the disclosure; and

FIG. 23 is a diagram schematically plotting temperatures (in degrees Celsius) of the semiconductor package of FIG. 22 as a function of a position (μm) along direction D shown in FIG. 22.

### DETAILED DESCRIPTION OF EMBODIMENTS

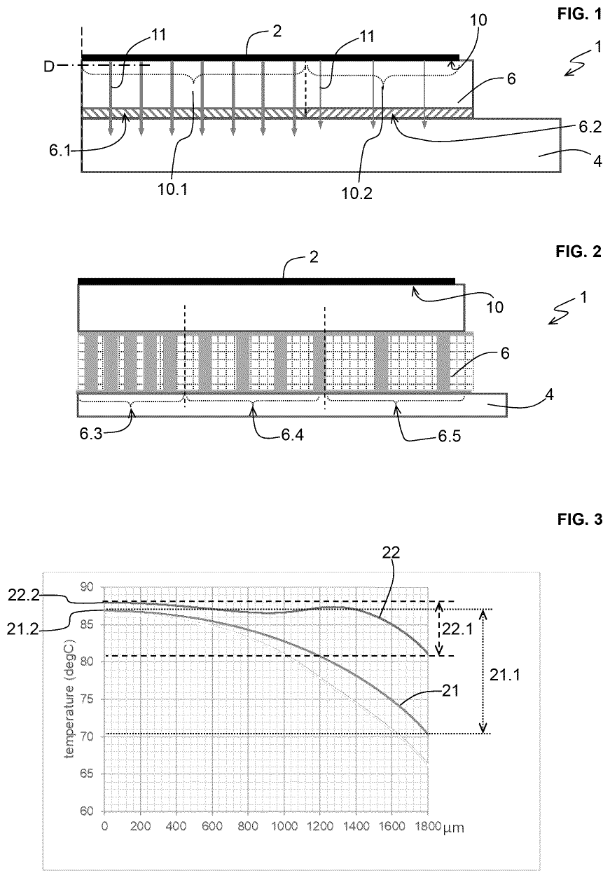

FIG. 1 shows a semiconductor package 1 comprising: a semiconductor device 2, a heat sink 4, and a plurality of vias 6 (shown individually in FIG. 2). The semiconductor package 1 may form a system in package (SIP). The semiconductor device 2 may be an embedded chip, which is embedded in an insulating layer. The semiconductor device 2 may comprise a microprocessor.

The plurality of vias 6 is arranged between (i) a device face 10 of the semiconductor device 2 and (ii) the heat sink 4. The device face 10 may be substantially planar. As the semiconductor device 2 may represent a flat volume, the device face 10 may be one of the two largest faces of this flat volume. The device face 10 may be substantially rectangular when the semiconductor device 2 has a parallelepipedal shape.

The vias 6 may be in direct contact with the heat sink 4 and/or with the device face 10. The vias 6 may be micro-vias 6. The vias 6 may be made out of an electrically conductive material, like e.g. copper. Alternatively, the vias 6 may be thermal vias, which conduct heat but not necessarily electricity.

The semiconductor device 2 can produce heat when it is operated, in particular, supplied with electricity. The vias 6 of the plurality of vias are configured to transfer heat from the semiconductor device 2 to the heat sink 4. The heat sink 4 may be configured to help in dissipating away heat produced by semiconductor device 2.

Arrows 11 in FIG. 1 illustrate heat flows flowing from the semiconductor device 2 toward the heat sink 4 via the vias 6. These heat flows depend on the surface density of vias 6: the larger the surface density, the larger the heat flow.

The semiconductor package 1 may further comprise: (i) a die supporting the semiconductor device 2, and (ii) a lead frame for carrying signals from and/or to the die. The die may be part of the semiconductor device 2. The lower face of the die may form the device face 10.

The lead frame may be part of the heat sink 4. The lead frame and/or the heat sink 4 may comprise a metallic layer, which may be made out of copper. Alternatively, the lead frame may be thermally connected with, for example directly mounted on, the heat sink.

As the plurality of vias 6 is configured to transfer heat from the semiconductor device to the heat sink, the plurality of vias 6 may be thermally connected with the semiconductor device 2 on the one hand and with the heat sink 4 on the other hand. On one side, the vias 6 may be arranged in direct contact with the die. On the other side, the vias 6 may be arranged in direct contact with the lead frame, hence with the heat sink 4.

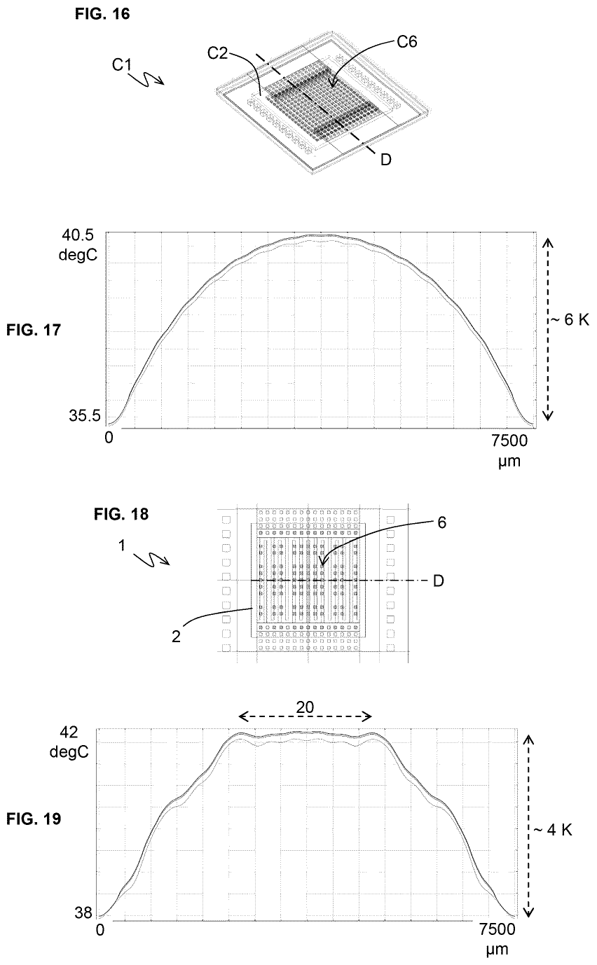

According to the present disclosure, the plurality of vias 6 forms a non-uniform distribution of the vias 6 over the device face 10. Examples of such non-uniform distribution are given hereinafter in relation to FIGS. 2 and 4 to 12. By contrast, in conventional semiconductor packages, the vias are uniformly distributed over the whole device face, mostly in a regular matrix arrangement as illustrated in FIG. 16.

The non-uniform distribution of vias 6 in the plurality of vias 6 may be defined in a plane parallel to the device face 10, for example in the cross-section of FIG. 1. The plurality of vias 6 may comprise two or more sets 6.1, 6.2 of vias 6, which sets 6.1, 6.2 have different surface densities of vias 6. Thus, the surface density of vias 6 in a first set 6.1 of vias 6 may be smaller than the surface density of vias 6 in a second set 6.2 of vias 6.

In the semiconductor package 1 of FIG. 1, a surface density of vias 6 over a first area 10.1 of the device face 10 may be larger than a surface density of vias 6 over a second area 10.2 of the device face 10. The first area 10.1 may form a central area of the device face 10, while the second area 10.2 may form a lateral area of the device face 10. The first area 10.1 and the second area 10.2 may also extend orthogonally to the plane of FIG. 1.

For example, the surface density of vias 6 over said first area 10.1 may be about 3 times larger than the surface density of vias 6 over the second area 10.2. Thus, a heat flux drained out of the first area 10.1 may be significantly larger than a heat flux drained out of the second area 10.2. Conversely, the first area 10.1 can be cooled down more than the second area 10.2 where the thermal resistance is relatively high. This can for example provide a relatively even thermal field by compensating large temperature gradients between the first area 10.1 and the second area 10.2, for example between the central and lateral areas.

The respective surface densities of first area 10.1 and of second area 10.2 may be selected such that the average temperature of first area 10.1 is about equal to or slightly lower than the average temperature of second area 10.2 when the semiconductor device 2 is being operated.

For example, the surface density of vias 6 over the first area 10.1 may be about 80% and the surface density of vias 6 over the second area 10.2 may be about 20%. In other words, the cumulated surface of vias represents 80% of the first area 10.1 but only 20% of the second area 10.2.

The surface density of vias 6 over the first area 10.1 may be substantially constant over the entirety of the first area 10.1. The surface density of vias 6 over the second area 10.2 may be substantially constant over the entirety of the second area 10.2.

Besides, the surface density of vias 6 over the first area 10.1 may be selected such that the thermal conductivity through the first area 10.1 is about 180 W/m/K. Also, the surface density of vias 6 over the second area 10.2 may be selected such that the thermal conductivity through the second area 10.2 is about 60 W/m/K.

FIG. 2 shows a schematic cross-section similar to FIG. 1 of a part of a semiconductor package 1 according to a second embodiment of the present disclosure. The cross-section of FIG. 2 could even be taken along a plane perpendicular to the plane of FIG. 1 or direction D, thus showing another part of the same semiconductor package 1 as FIG. 1.

The afore-detailed description of FIG. 1 may be applied to FIG. 2, except for the hereinafter-mentioned noticeable differences. An element of semiconductor package 1 of FIG. 2 is given the same reference sign as an element having a similar structure or function in FIG. 1.

Like in FIG. 1, the semiconductor package 1 of FIG. 2 comprises a semiconductor device 2, a heat sink 4, and a plurality of vias 6 arranged between (i) a device face 10 of the semiconductor device 2 and (ii) the heat sink 4. In the unscaled FIG. 2 the grey areas illustrate vias 6, while the hatched areas illustrate some more thermally insulating material that is located in between neighboring vias 6.

The semiconductor package 1 of FIG. 2 differs from the semiconductor package 1 of FIG. 1 in that, instead of the two sets of vias 6.1 and 6.2 of FIG. 1, the plurality of vias 6 may comprise three sets of vias 6, respectively the set of vias 6.3 (left of FIG. 1), the set of vias 6.4 (middle of FIG. 1) and the set of vias 6.5 (right of FIG. 1), which have different respective surface densities of vias 6. The vias 6 of the sets 6.3, 6.4 and 6.5 are arranged in front of different areas of the device face 10.

The surface density of vias 6 in the first set 6.3 of vias may be the largest, the surface density of vias 6 in the third set 6.5 of vias may be the smallest, and the surface density of vias 6 in the second set 6.4 of vias may stand between the surface density of the first set of vias 6.3 and the surface density of the third set of vias 6.5. For example, the surface density of vias 6 in the first set of vias 6.3 may be about 80%, the surface density of vias 6 in the second set of vias 6.4 may be about 40%, and the surface density of vias 6 in the third set of vias 6.5 may be about 20%.

On the diagram of FIG. 3 are schematically plotted a first curve 21 and a second curve 22, both showing temperatures (in degrees Celsius) as a function of a position (in micrometers, called “distance across channel”) along direction D shown in FIG. 1. The first curve 21 corresponds to a conventional semiconductor package, e.g. the one illustrated in FIG. 16, while the second curve 22 corresponds to the semiconductor package 1 of FIG. 1. The first curve 21 and the second curve 22 may be obtained by computer simulation (e.g. via a Finite Element Simulation software), or by measuring temperatures on actual semiconductor packages.

In the conventional semiconductor package the vias are uniformly distributed, unlike in the semiconductor package 1 of FIG. 1. On the diagram of FIG. 3 it appears that an overall temperature gradient 21.1 (˜17° C.=87° C.−70° C.) in the conventional semiconductor package is much larger than an overall temperature gradient 22.1 (˜7° C.=88° C.−81° C.) in the semiconductor package 1.

Similar observations can be made on temperatures obtained for other portions of the device face 10, not only along direction D. As a result, a not-shown thermal field in the semiconductor device 2 can be more even or balanced than a thermal field in the conventional semiconductor device.

Too large overall temperature gradients, or too uneven thermal fields, may cause the distribution of electrical current to be uneven in a conventional semiconductor device (curve 21), which in turn develops weak spots at the channel level. Eventually, too large overall temperature gradients may cause the device to operate in a thermally unstable regime, which can lead to thermal runaway and eventually to a catastrophic failure. Such problems are much less likely to occur with the semiconductor package 1 (curve 22) than with the conventional semiconductor package (curve 21).

Further on the diagram of FIG. 3 it appears that a maximum temperature 21.2 (˜87° C.) reached for the conventional semiconductor device is approximately equal to a maximum temperature 22.2 (˜88° C.) reached for the semiconductor device 2 of semiconductor package 1.

The maximum temperature reached in a semiconductor device in operation should be maintained under a given threshold in order to enhance the service life of the semiconductor device. In the case of curves 21 and 22, the maximum temperatures 21.2 and 22.2 are about the same, so they can be expected to have the same influence on the service lives of the conventional semiconductor device and of the semiconductor device 2.

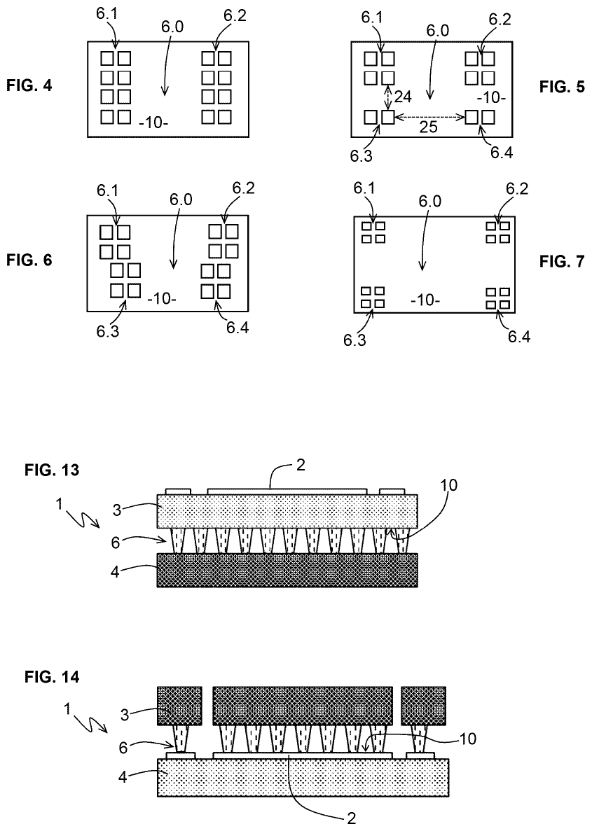

FIGS. 4 to 12 show embodiment of the present disclosure, wherein the pluralities of vias 6 are arranged to form non-uniform distributions of vias 6 over a device face 10 of the corresponding semiconductor device. The distributions of vias 6 might show some local uniformity, but the overall distribution is non-uniform.

The various non-uniform distributions of vias 6 yield various shapes of thermal fields and temperature gradients (not shown) in the semiconductor devices in operation. Thus, the thermal fields in a semiconductor device according to the present disclosure may be designed in accordance with various uses of the semiconductor packages.

The exemplary implementations shown in FIGS. 4 to 12 have arrangements of vias as described in the following. These vias are represented as relatively large and in small numbers for the sake of legibility, but they could as well be smaller and more numerous.

FIG. 4 shows, from left to right, a first set of vias 6.1, an empty region 6.0 free from vias, and a second set of vias 6.2. The vias are arranged in matrices in the first set of vias 6.1 and in the second set of vias 6.2. All the vias have substantially the same size and shape, and the distribution of plurality of vias is non-uniform over the entire device face 10.

FIG. 5 shows, from left to right and from top to bottom, a first set of vias 6.1, a large empty region 6.0 free from vias, a second set of vias 6.2, a third set of vias 6.3 and a fourth set of vias 6.4. In the first set of vias 6.1 and in the second set of vias 6.2, the vias are arranged in different matrices. The first set of vias 6.1 and in the second set of vias 6.2 respectively comprise two vias arranged in rows. The third set of vias 6.3 and the first set of vias 6.1 form a column with an empty space between them. Likewise, the fourth set of vias 6.4 and the second set of vias 6.2 form a column with an empty space between them. All the vias have substantially the same size and shape. The non-uniform distribution of the vias may comprise rows and columns, whereby a first gap 24 between neighboring rows may vary in the plurality of vias, and a second gap 25 between neighboring columns may vary in the plurality of vias. The first gap 24 may be different from the second gap 25; the first gap 24 (between rows) may be smaller than the second gap 25 (between columns).

FIG. 6 shows, from left to right and from top to bottom, a first set of vias 6.1, an empty region 6.0 free from vias, a second set of vias 6.2, a third set of vias 6.3 and a fourth set of vias 6.4. Each one of the first, second, third and fourth sets of vias has four vias arranged in a square matrix; the third set of vias 6.3 is arranged below but offset from the first set of vias 6.1. Likewise, the fourth set of vias 6.4 is arranged below but offset from the second set of vias 6.2. All the vias have substantially the same size and shape.

FIG. 7 shows, from left to right and from top to bottom, a first set of vias 6.1, a second set of vias 6.2, a third set of vias 6.3 and a fourth set of vias 6.4. The first, second, third and fourth sets of vias are respectively arranged in the corners of the device face 10 with empty regions between them. All the vias have substantially the same size and shape.

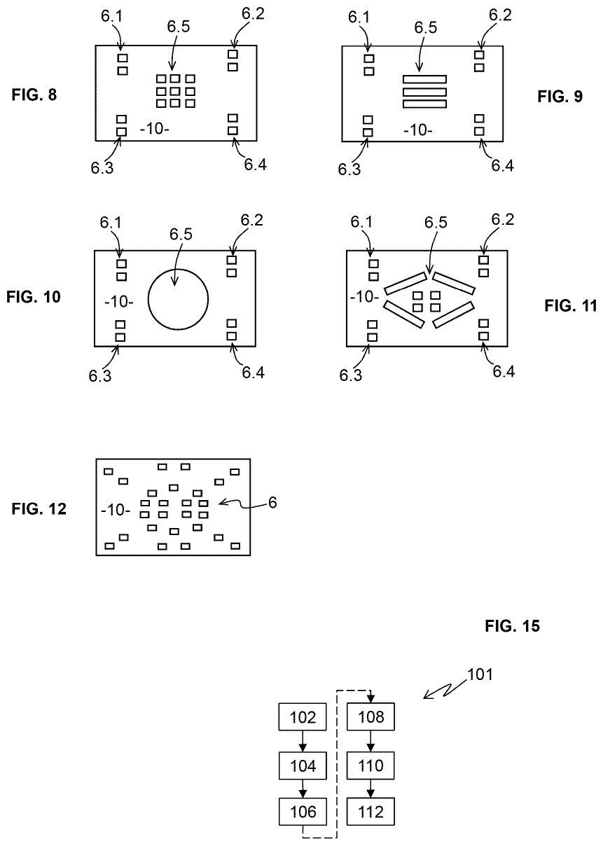

FIG. 8 shows, from left to right and from top to bottom, a first, a second, a third and a fourth sets of two vias each 6.1, 6.2, 6.3 and 6.4, which are respectively arranged in the four corners of the device face 10. In addition, a central set of vias 6.5 has nine vias. The corners are less densely populated by vias than the central region. Empty regions separate the sets of vias from one another; all vias have substantially the same size and shape.

FIG. 9 shows an arrangement of vias similar to FIG. 8, except that the central set of vias 6.5 has larger vias in the shape of rectangles.

FIG. 10 shows an arrangement of vias similar to FIG. 8, except that the central set of vias 6.5 has only one large via in the shape of a disk.

FIG. 11 shows an arrangement of vias similar to FIG. 8, except that the central set of vias 6.5 is formed of a matrix of four small vias in the shape of squares, this matrix being surrounded by four larger, rectangular vias forming a diamond shape.

FIG. 12 shows a non-uniform distribution of vias along radial directions. Lateral regions are less densely populated by vias than a central region; the vias may be arranged symmetrically with respect to a horizontal and vertical axes passing through the center of the device face 10.

As visible in the FIGS. 9 to 11, the plurality of vias may comprise large vias and small vias. A large via has a larger cross-sectional area than a small via when measured parallel to the device face 10 (e.g. in the plane of the Figures). A ratio of a cross-sectional area of a large via over a cross-sectional area of a small via may be of about 4 in the example of FIGS. 9 and 11, and of about 50 in the example of FIG. 10. The larges vias may have a width of about 700 μm, and/or the small vias may have a width of about 100 μm, when measured in a plane parallel to the device face 10.

Further in the examples of FIGS. 9 to 11, the plurality of vias may comprise two groups of vias, the shape of the vias of the one group differing from the shape of the vias of the other group, when viewed in a cross-section parallel to the device face 10 (e.g. in the plane of the Figures). The vias may for example have the shapes of rectangles, squares, or circles. In the example of FIG. 9 or 11, the plurality of vias may comprise a group of square vias and a group of rectangular vias, which may be surrounded by a group of square vias.

In the example of FIG. 7, 8, 9, 10 or 12, the non-uniform distributions of vias may be designed such that the plurality of vias comprises a central symmetry and axial symmetries. Alternatively, in the example of FIG. 5, the non-uniform distribution of vias may be designed such that such that the plurality of vias does not present any symmetry.

In the example of FIG. 12, the non-uniform distribution of vias may be designed such that a gap between two neighboring vias increases as the distance of the vias to the center of the device face 10 increases.

FIGS. 13 and 14 show semiconductor packages 1 according to different implementations of the present disclosure. The semiconductor packages 1 of both FIGS. 13 and 14 are similar in that they comprise a semiconductor device 2, which may be mounted on a die 3, a heat sink 4, optionally including a lead frame, and a plurality of vias 6, which is configured to transfer heat from the semiconductor device 2 to the heat sink 4 and which forms a non-uniform distribution of vias of a device face 10.

In the semiconductor packages 1 of both FIGS. 13 and 14 the plurality of vias 6 may be in direct contact with the heat sink 4 (here with its lead frame). The semiconductor devices 2 of both FIGS. 13 and 14 may be chips embedded in thermally insulating materials.

The semiconductor packages 1 of FIGS. 13 and 14 have different constructions as described in the following.

In FIG. 13, the plurality of vias 6 may be in contact with the die 3 and the heat transfer or cooling of the semiconductor device 2 may occur through a bottom side or backside of the semiconductor device 2 via the die 3.

By contrast, the plurality of vias 6 of FIG. 14 may be in contact with the semiconductor device 2 and the heat transfer, or cooling, of the semiconductor device 2 may occur through a top or front side of the semiconductor device 2. In this implementation example, the vias may be configured to supply electricity to the semiconductor device 2.

FIG. 15 illustrates a method 101, according to a second embodiment of the present disclosure, for manufacturing a semiconductor package according to the first embodiment of the present disclosure. The manufacturing method 101 comprises an operation 108 of providing a semiconductor device, which produces heat when being operated. Further, the method 101 comprises an operation 110 of providing a heat sink, and an operation 112 of forming, for example by means of a laser beam, a plurality of vias arranged between a device face of the semiconductor device and the heat sink. The vias are configured to transfer heat from the semiconductor device to the heat sink, wherein the plurality of vias forms a non-uniform distribution of vias over said device face.

The manufacturing method 101 makes it possible to manufacture a semiconductor package according to the present disclosure.

The manufacturing method 101 may initially comprise an operation 102 of implementing a model of the semiconductor package on a computer, for example via a software. Further, the method 101 may comprise an operation 104 of inputting a set of operating conditions in the computer, for example via a software, and an operation 106 of processing, with the computer and possibly a software, a simulation of the thermal field in the semiconductor device as a function of said set of operating conditions.

In service, the semiconductor package according to the present disclosure makes it possible to accurately adapt the distribution of heat to various design requirements that apply to the semiconductor device and to the semiconductor package. Such possibilities may also be understood by comparing FIGS. 18 to 23 with FIGS. 16 and 17. In order to allow such a comparison, the semiconductor devices of FIGS. 16, 18, 20 and 22 have substantially the same design that would yield the same thermal fields if the semiconductor packages had inter alia the same distribution of vias.

FIG. 16 shows a part of a conventional semiconductor package C1, wherein the plurality of vias C6 may be arranged in a uniform matrix distribution. The diagram of FIG. 17 schematically plots temperatures of the conventional semiconductor package C1 of FIG. 16 as a function of a position along direction D shown in FIG. 16. The temperature-position curve of FIG. 17 shows a bell shape with a hot spot in the center of the semiconductor device C2 and a temperature gradient of about 6 degrees Kelvin (or Celsius) between the center and the sides of the semiconductor device C2.

FIGS. 18, 20 and 22 illustrate respective parts of semiconductor packages 1 according to the present disclosure and having non-uniform distributions in their pluralities of vias 6. The diagrams of FIGS. 19, 21 and 23 schematically plot the temperatures of the respective semiconductor packages 1 of FIGS. 18, 20 and 22 as a function of a position along direction D shown in FIGS. 18, 20 and 22.

The semiconductor package 1 of FIG. 18 may have a plurality of vias 6 distributed in several matrices, which have various numbers of rows and columns and which are separated by empty rows and empty columns. The plurality of vias of FIG. 18 shows a central symmetry and axial symmetries along not shown horizontal and vertical axes.

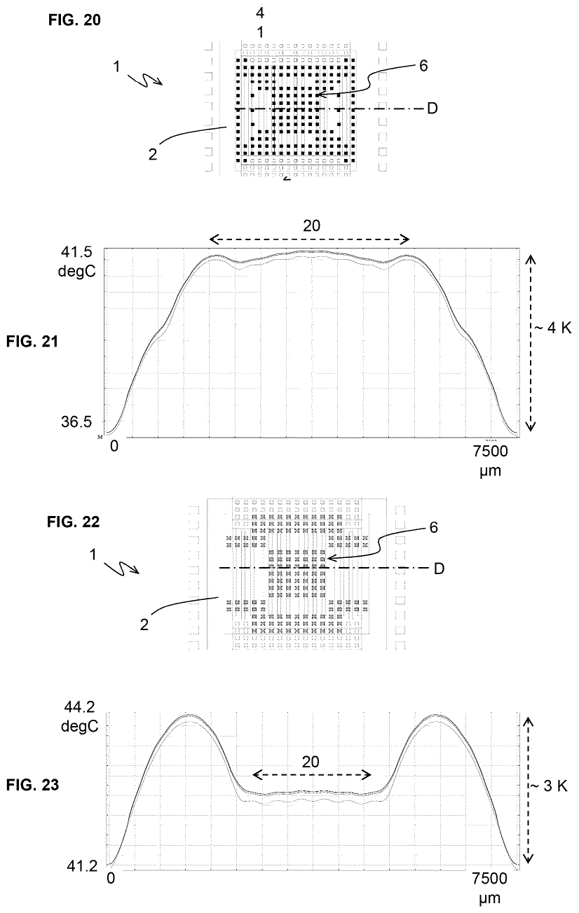

The temperature-position curve shown in FIG. 19 may have a substantially flat top portion 20 spanning about 3000 μm and an overall temperature gradient of about 4 degrees Kelvin. As the temperature in the semiconductor device 2 of FIG. 20 may remain substantially constant, the heat may be evenly distributed on a large central region 20 of the semiconductor device 2. There is no hot spot like in the conventional semiconductor package C1 of FIG. 16.

The semiconductor package 1 of FIG. 20 may have a plurality of vias 6 distributed differently from the one of FIG. 18. The plurality of vias FIG. 20 may include several matrices, which have various numbers of rows and columns and which may be separated by empty rows and columns free of vias. The plurality of vias of FIG. 20 shows central and axial symmetries.

The temperature-position curve shown in FIG. 21 is similar to the one of FIG. 19, with a substantially flat top portion 20 spanning about 3500 μm and an overall temperature gradient of about 4 degrees Kelvin.

The semiconductor package 1 of FIG. 22 may have a plurality of vias distributed differently from the one of FIG. 18 or 20. The plurality of vias FIG. 22 may include (i) a large central matrix, (ii) two medium-sized top and bottom matrix, and (iii) four small lateral matrices. The matrices of FIG. 22 may have similar surface densities of vias, but different numbers of rows and columns, and they may be separated by empty regions free of vias. The plurality of vias of FIG. 22 shows central and axial symmetries.

The temperature-position curve shown in FIG. 23 differs from the one of FIG. 19 or 21. The curve of FIG. 23 shows a substantially flat central portion 20 spanning about 3000 μm and two hotter lateral bell-shaped portions. The overall temperature gradient of about 3 degrees Kelvin and the central portion is 1.5 degrees cooler than the lateral bell-shaped portions.

The present disclosure has been described in conjunction with various embodiments as examples as well as implementations. However, other variations can be understood and effected by those persons skilled in the art and practicing the claimed matter, from the studies of the drawings, this disclosure and the independent claims. In the claims as well as in the description the word “comprising” does not exclude other elements or operations and the indefinite article “a” or “an” does not exclude a plurality. A single element or other unit may fulfill the functions of several entities or items recited in the claims. The mere fact that certain measures are recited in the mutual different dependent claims does not indicate that a combination of these measures cannot be used in an advantageous implementation. Also, the various implementation forms and examples described in the present disclosure may be combined, when technically feasible, to define additional implementation forms which are also part of this disclosure.

What is claimed is:

1. A semiconductor package, comprising:
a semiconductor device which produces heat when being operated,
a heat sink, and
a plurality of vias arranged between a device face of the semiconductor device and the heat sink, the plurality of vias being configured to transfer heat from the semiconductor device to the heat sink,
wherein the plurality of vias forms a non-uniform distribution of vias over the device face.

2. A semiconductor package according to claim 1, wherein the plurality of vias comprises at least two sets of vias having different respective surface densities of vias.

3. A semiconductor package according to claim 1, wherein a surface density of vias over a first area of the device face is larger than a surface density of vias over a second area of the device face.

4. A semiconductor package according to claim 3, wherein the surface density of vias over the first area of the device face is between 2 and 100 times larger than the surface density of vias over the second area of the device face.

5. A semiconductor package according to claim 3, wherein the first area of the device face forms a central area of the device face, and wherein the second area of the device face forms a lateral area of the device face, the lateral area being a peripheral area surrounding the central area.

6. A semiconductor package according to claim 3, wherein the first area of the device face represents between 20% and 60% of an entire area of the device face, and/or wherein the second area of the device face represents between 40% and 80% of the entire area of the device face.

7. A semiconductor package according to claim 3, wherein the surface density of vias over the first area of the device face is between 20% and 100%, preferably between 20% and 80%, and/or
wherein the surface density of vias over the second area of the device face is between 0% and 50%, preferably between 10% and 40%.

8. A semiconductor package according to claim 1, wherein the plurality of vias comprises large vias and small vias, a large via having a larger cross-sectional area than a small via when measured parallel to the device face.

9. A semiconductor package according to claim 1, wherein a ratio of a cross-sectional area of a large via over a cross-sectional area of a small via is between 1.5 and 1000, preferably between 10 and 500.

10. A semiconductor package according to claim 1, wherein the vias are thermal vias.

11. A semiconductor package according to claim 1, wherein the vias are in direct contact with the heat sink.

12. A semiconductor package according to claim 1, wherein the plurality of vias comprises at least two groups of vias, wherein the shapes of the vias differ from one group of vias to another group of vias when viewed in a cross-section parallel to the device face, the shapes of the vias being selected among rectangle, square, ellipse and circle.

13. A semiconductor package according to claim 1, wherein the non-uniform distribution of vias is designed such that the plurality of vias comprises at least a central symmetry, a radial symmetry or an axial symmetry.

14. A semiconductor package according to claim 1, wherein the non-uniform distribution of vias is designed such that a gap between two neighboring vias increases as a distance of the two neighboring vias to a center of the device face increases.

15. A semiconductor package according to claim 1, wherein the non-uniform distribution of the vias comprises rows and columns, whereby a first gap between consecutive rows varies in the plurality of vias, and a second gap between consecutive columns varies in the plurality of vias, the first gap being different from the second gap.

16. A semiconductor package according to claim 1, wherein the semiconductor device is embedded in a thermally insulating material.

17. A semiconductor package according to claim 1, wherein the semiconductor package further comprises a die supporting the semiconductor device, and a lead frame for carrying signals from and/or to the die, and wherein the lead frame is thermally connected with the heat sink.

18. A method for manufacturing a semiconductor package, comprising:
providing a semiconductor device which produces heat when being operated,
providing a heat sink, and
forming, by means of a laser beam, a plurality of vias arranged between a device face of the semiconductor device and the heat sink, the vias being configured to transfer heat from the semiconductor device to the heat sink,
wherein the plurality of vias forms a non-uniform distribution of vias over the device face.

19. The method according to claim 18, further comprising:
implementing a model of the semiconductor package on a computer;
inputting a set of operating conditions in the computer; and
processing, with the computer, a simulation of a thermal field in the semiconductor device as a function of the set of operating conditions.
